(19) United States
(12) Patent Application Publication
(10) Pub. No.: US 2026/0353745 A1
(43) Pub. Date: Nov. 5, 2026

(54) SEMICONDUCTOR DEVICE STRUCTURE WITH GATE STACK

(71) Applicant: Taiwan Semiconductor Manufacturing Company, Ltd., Hsinchu (TW)

(72) Inventors: Pin-Chun SHEN, Changhua County (TW); Li-Ying WU, Hsinchu County (TW); Shih-Hsun CHANG, Hsinchu (TW); Chih-Hao CHANG, Hsin-Chu (TW); Jen-Hsiang LU, Taipei City (TW)

(73) Assignee: Taiwan Semiconductor Manufacturing Company, Ltd., Hsinchu (TW)

(21) Appl. No.: 19/745,130

(22) Filed: Jul. 17, 2026

Related U.S. Application Data
(62) Division of application No. 17/701,997, filed on Mar. 23, 2022.

(51) Int. Cl. H10D 64/01; H10D 30/01; H10D 30/67; H10D 62/10; H10D 84/01; H10D 84/03

(52) U.S. Cl. CPC H10D 64/021; H10D 30/031; H10D 30/6735; H10D 30/6755; H10D 30/6757; H10D 62/118; H10D 84/0128; H10D 84/0147; H10D 84/038

(57) ABSTRACT

A semiconductor device structure is provided. The semiconductor device structure includes a channel structure over a substrate. The semiconductor device structure also includes a gate stack covering an intermediate portion of the channel structure. The semiconductor device structure further includes a gate spacer extending along a sidewall of the gate stack and covering an edge portion of the channel structure. In addition, the semiconductor device structure includes a metal-containing oxide layer between the gate spacer and the edge portion of the channel structure.

### PRIORITY CLAIM AND CROSS-REFERENCE

This Application is a Divisional of U.S. Application No. 17/701,997, filed on Mar. 23, 2022, the entirety of which is incorporated by reference herein.

### BACKGROUND

The semiconductor integrated circuit (IC) industry has experienced rapid growth. Technological advances in IC materials and design have produced generations of ICs. Each generation has smaller and more complex circuits than the previous generation.

Over the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, these advances have increased the complexity of processing and manufacturing ICs. Since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1B are top views of various stages of a process for forming a portion of a semiconductor device structure, in accordance with some embodiments.

FIGS. 2A-2D are cross-sectional views of various stages of a process for forming a portion of a semiconductor device structure, in accordance with some embodiments.

FIGS. 3A-3K are cross-sectional views of various stages of a process for forming a portion of a semiconductor device structure, in accordance with some embodiments.

FIGS. 4A-4B are cross-sectional views of various stages of a process for forming a portion of a semiconductor device structure, in accordance with some embodiments.

FIGS. 5A-5B are cross-sectional views of various stages of a process for forming a portion of a semiconductor device structure, in accordance with some embodiments.

FIGS. 6A-6C are cross-sectional views of various stages of a process for forming a portion of a semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. Where applicable, the term “substantially” may also relate to 90% or higher, such as 95% or higher, especially 99% or higher, including 100% of what is specified. Furthermore, terms such as "substantially parallel" or "substantially perpendicular" are to be interpreted as not to exclude insignificant deviation from the specified arrangement and may include for example deviations of up to 10 degrees in some embodiments. The word "substantially" does not exclude "completely" e.g. a composition which is "substantially free" from Y may be completely free from Y in some embodiments.

Terms such as "about" in conjunction with a specific distance or size are to be interpreted so as not to exclude insignificant deviation from the specified distance or size and may include for example deviations of up to 10% of what is specified in some embodiments. The term "about" in relation to a numerical value x may mean x ±5 or 10% of what is specified in some embodiments.

Embodiments of the disclosure may relate to FinFET structure having fins. The fins may be patterned using any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. However, the fins may be formed using one or more other applicable processes.

Embodiments of the disclosure may relate to nanostructure transistor structures. The nanostructure transistor structures (e.g. nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. In some embodiments, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure transistor structure.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

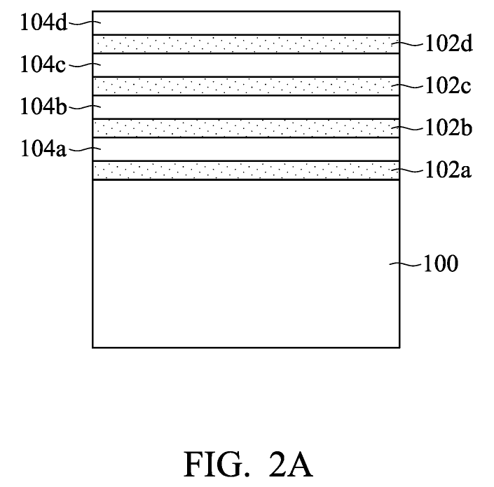

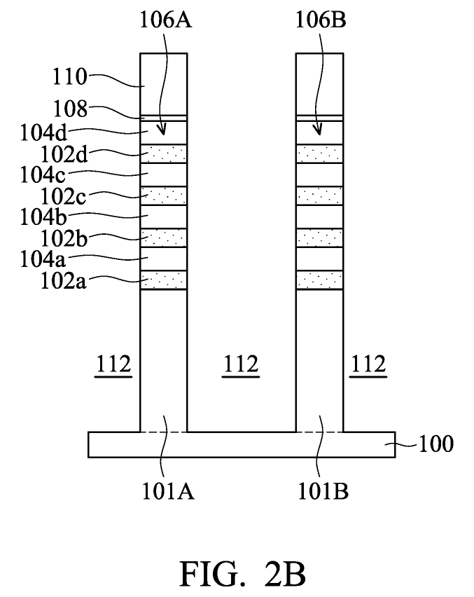

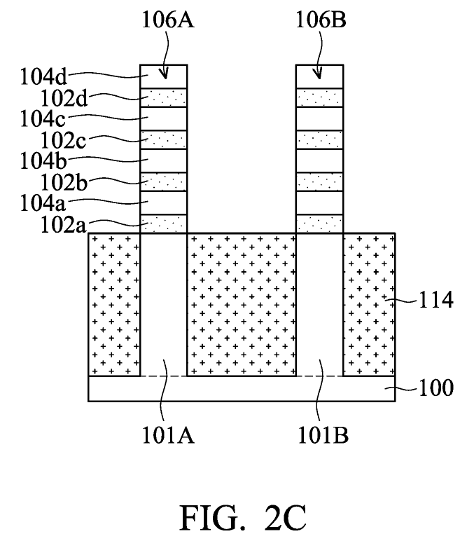

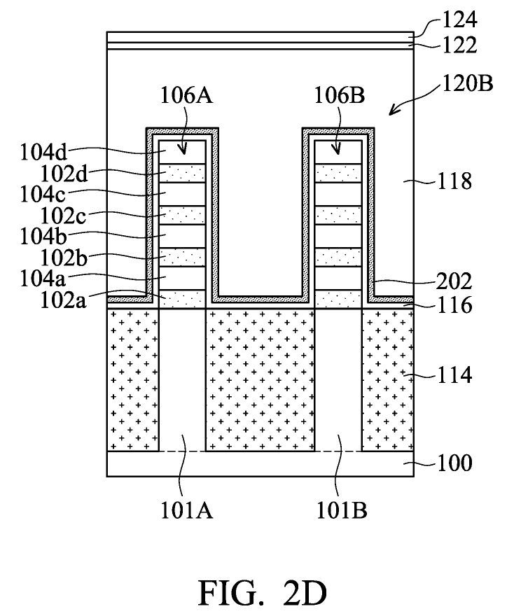

FIGS. 2A-2D are cross-sectional views of various stages of a process for forming a portion of a semiconductor device structure, in accordance with some embodiments. As shown in FIG. 2A, a semiconductor substrate 100 is received or provided. In some embodiments, the semiconductor substrate 100 is a bulk semiconductor substrate, such as a semiconductor wafer. The semiconductor substrate 100 may include silicon or other elementary semiconductor materials such as germanium. The semiconductor substrate 100 may be un-doped or doped (e.g., p-type, n-type, or a combination thereof). In some embodiments, the semiconductor substrate 100 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 100 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 100 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 100 includes a multi-layered structure. For example, the semiconductor substrate 100 includes a silicon-germanium layer formed on a bulk silicon layer.

As shown in FIG. 2A, a semiconductor stack having multiple semiconductor layers is formed over the semiconductor substrate 100, in accordance with some embodiments. In some embodiments, the semiconductor stack includes multiple semiconductor layers 102a, 102b, 102c, and 102d, and the semiconductor stack also includes multiple semiconductor layers 104a, 104b, 104c, and 104d. In some embodiments, the semiconductor layers 102a-102d and the semiconductor layers 104a-104e are laid out alternately, as shown in FIG. 2A.

In some embodiments, the semiconductor layers 102a-102d function as sacrificial layers that will be removed in subsequent processes. The semiconductor layers 104a-104d may be used to form channel structures of one or more transistors after the removal of the semiconductor layers 102a-102d.

In some embodiments, the semiconductor layers 104a-104d that will be used to form channel structures are made of a material that is different than that of the semiconductor layers 102a-102d. In some embodiments, the semiconductor layers 104a-104d are made of or include silicon or silicon germanium. In some embodiments, the semiconductor layers 102a-102d are made of or include silicon germanium with different atomic concentrations of germanium than that of the semiconductor layers 104a-104d, so as to achieve different etching selectivity and/or different oxidation rates during subsequent processing. In some embodiments, the semiconductor layer 102a-102d have a greater atomic concentration of germanium that that of the semiconductor layers 104a-104d. In some embodiments, the semiconductor layer 104a-104d are substantially free of germanium. In some other embodiments, the semiconductor layers 104a-104d are made of or include silicon germanium, and the semiconductor layer 102a-102d are made of or include silicon.

The present disclosure contemplates that the semiconductor layers 102a-102d and the semiconductor layers 104a-104d include any combination of materials (such as semiconductor materials) that can provide desired etching selectivity, desired oxidation rate differences, and/or desired performance characteristics (e.g., materials that maximize current flow).

In some embodiments, the semiconductor layers 102a-102d and 104a-104d are formed using multiple epitaxial growth operations. Each of the semiconductor layers 102a-102d and 104a-104d may be formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof.

In some embodiments, the semiconductor layers 102a-102d and 104a-104d are grown in-situ in the same process chamber. In some embodiments, the growth of the semiconductor layers 102a-102d and 104a-104d are alternately and sequentially performed in the same process chamber to complete the formation of the semiconductor stack. In some embodiments, the vacuum of the process chamber is not broken before the epitaxial growth of the semiconductor stack is accomplished.

Afterwards, hard mask elements are formed over the semiconductor stack to assist in a subsequent patterning of the semiconductor stack. One or more photolithography processes and one or more etching processes are used to pattern the semiconductor stack into fin structures 106A and 106B, as shown in FIG. 2B in accordance with some embodiments. The fin structures 106A-106B may be patterned by any suitable method. For example, the fin structures 106A-106B may be patterned using one or more photolithography processes, including double-patterning or multi-patterning processes. Double-patterning or multi-patterning processes may combine photolithography and self-aligned processes, allowing patterns to be created that have, for example, pitches smaller than what is otherwise obtainable using a single, direct photolithography process.

The semiconductor stack is partially removed to form trenches 112, as shown in FIG. 2B. Each of the fin structures 106A-106B may include portions of the semiconductor layers 102a-102d and 104a-104d and protruding portions of the semiconductor substrate 100. The semiconductor substrate 100 may also be partially removed during the etching process that forms the fin structures 106A-106B. Protruding portions of the semiconductor substrate 100 that remain form the semiconductor fins 101A and 101B, as shown in FIG. 2B.

Each of the hard mask elements may include a first mask layer 108 and a second mask layer 110. The first mask layer 108 and the second mask layer 110 may be made of different materials. The first mask layer 108 may be made of silicon nitride, silicon oxynitride, silicon carbide, one or more other suitable materials, or a combination thereof. The second mask layer 110 may be made of or include silicon oxide, germanium oxide, silicon germanium oxide, one or more other suitable materials, or a combination thereof.

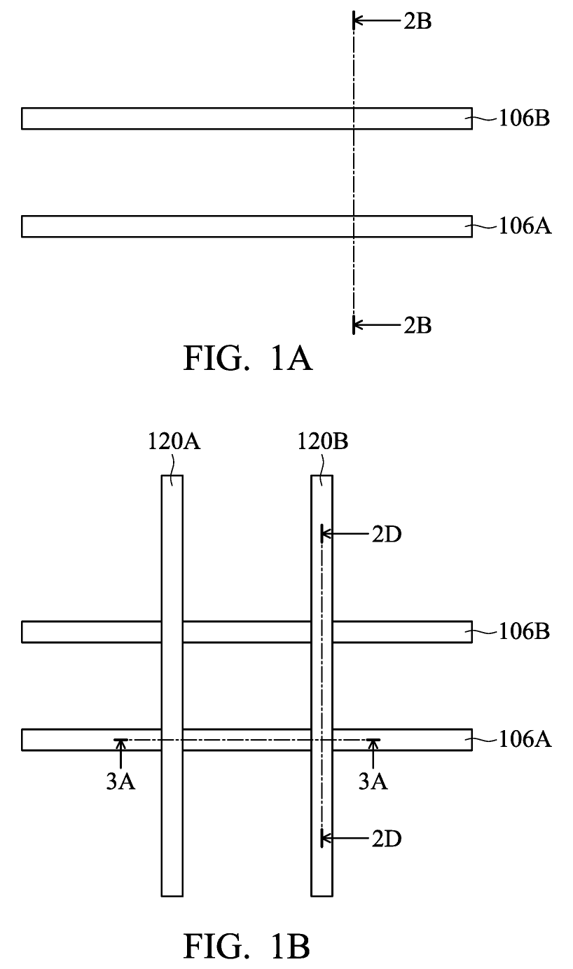

FIGS. 1A-1B are top views of various stages of a process for forming a portion of a semiconductor device structure, in accordance with some embodiments. In some embodiments, the fin structures 106A-106B are oriented lengthwise. In some embodiments, the extending directions of the fin structures 106A-106B are substantially parallel to each other, as shown in FIG. 1A. In some embodiments, FIG. 2B is a cross-sectional view of the structure taken along the line 2B-2B in FIG. 1A.

As shown in FIG. 2C, an isolation structure 114 is formed to surround lower portions of the fin structures 106A-106B, in accordance with some embodiments. In some embodiments, one or more dielectric layers are deposited over the fin structures 106A-106B and the semiconductor substrate 100 to overfill the trenches 112. The dielectric layers may be made of silicon oxide, silicon oxynitride, borosilicate glass (BSG), phosphoric silicate glass (PSG), borophosphosilicate glass (BPSG), fluorinated silicate glass (FSG), low-k material, porous dielectric material, one or more other suitable materials, or a combination thereof. The dielectric layers may be deposited using a flowable chemical vapor deposition (FCVD) process, an atomic layer deposition (ALD) process, a chemical vapor deposition (CVD) process, one or more other applicable processes, or a combination thereof.

Afterwards, a planarization process is used to partially remove the dielectric layers. The hard mask elements (including the first mask layer 108 and the second mask layer 110) may also function as a stop layer of the planarization process. The planarization process may include a chemical mechanical polishing (CMP) process, a grinding process, a dry polishing process, an etching process, one or more other applicable processes, or a combination thereof. Afterwards, one or more etching back processes are used to partially remove the dielectric layers. As a result, the remaining portion of the dielectric layers forms the isolation structure 114. Upper portions of the fin structures 106A-106B protrude from the top surface of the isolation structure 114, as shown in FIG. 2C.

Afterwards, the hard mask elements (including the first mask layer 108 and the second mask layer 110) are removed. Alternatively, in some other embodiments, the hard mask elements are removed or consumed during the planarization process and/or the etching back process that forms the isolation structure 114.

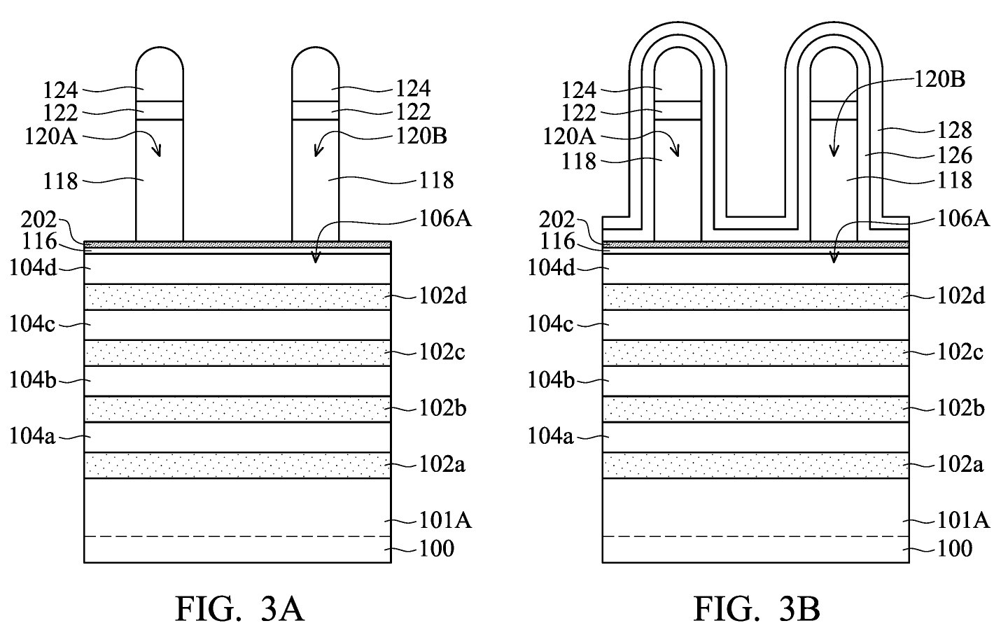

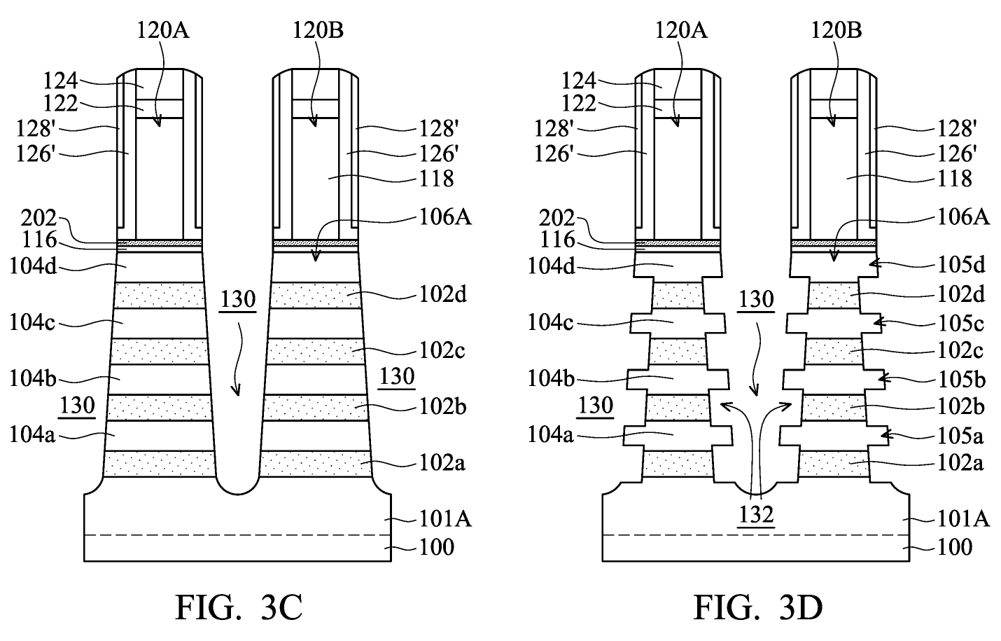

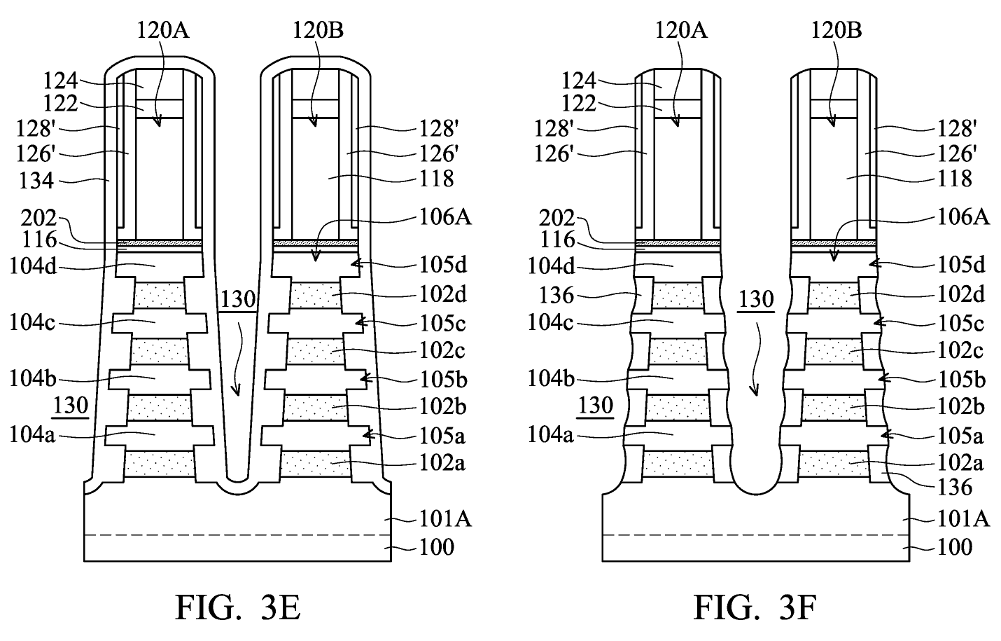

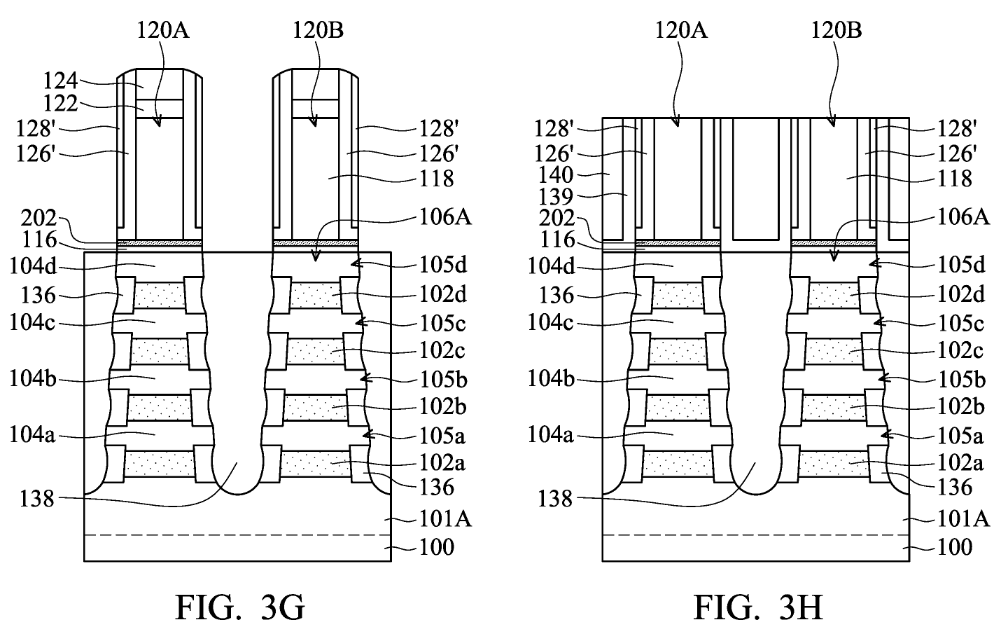

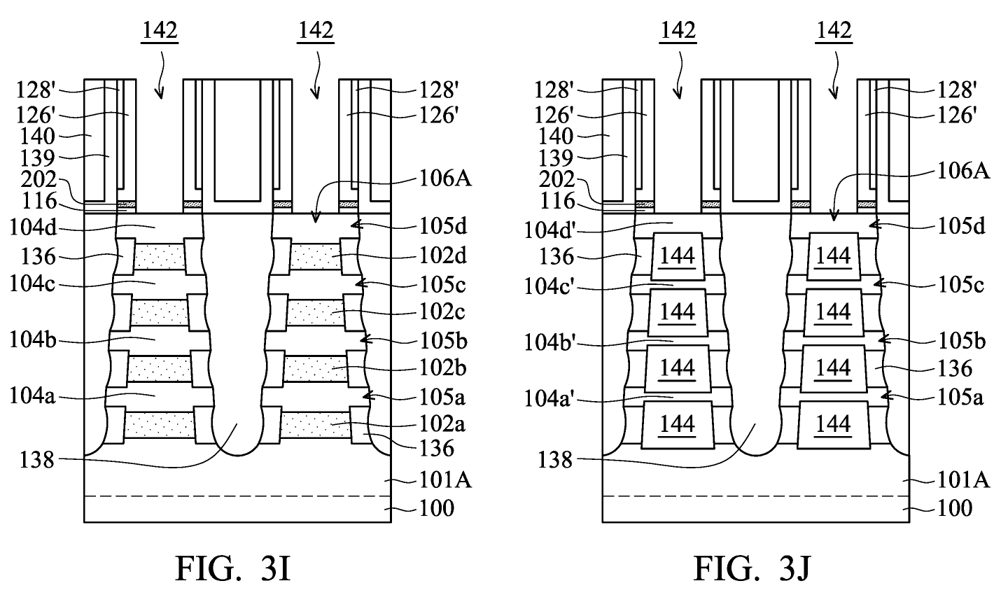

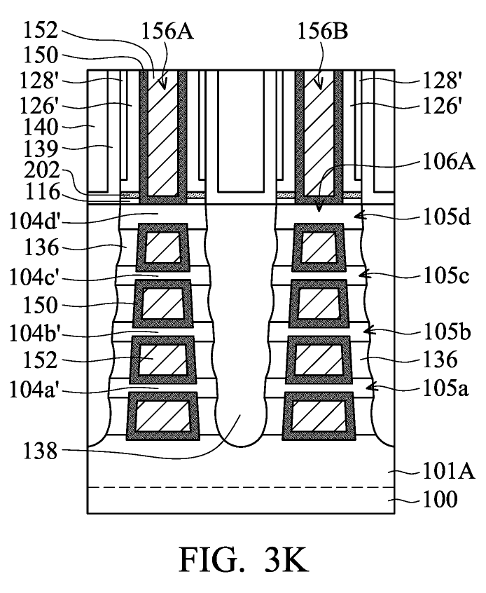

Afterwards, dummy gate stacks 120A and 120B are formed to extend across the fin structures 106A-106B, as shown in FIG. 1B in accordance with some embodiments. In some embodiments, FIG. 2D is a cross-sectional view of the structure taken along the line 2D-2D in FIG. 1B. FIGS. 3A-3K are cross-sectional views of various stages of a process for forming a portion of a semiconductor device structure, in accordance with some embodiments. In some embodiments, FIG. 3A is a cross-sectional view of the structure taken along the line 3A-3A in FIG. 1B.

As shown in FIGS. 2D and 3A, an oxide layer 116 is deposited over the fin structure 106A and 106B and the isolation structure 114, in accordance with some embodiments. In some embodiments, the oxide layer 116 extends along the top surface and the sidewalls of the semiconductor layer 104d that may function as one or more channel structures. The oxide layer 116 further extends along the sidewalls of the semiconductor layers 104a-104c that may function as channel structures. The oxide layer 116 may be used as a dummy gate dielectric layer. The oxide layer 116 may be made of or include silicon oxide or another suitable material. The oxide layer 116 may be deposited using an ALD process, a CVD process, a thermal oxidation process, one or more other applicable processes, or a combination thereof.

Afterwards, a dielectric layer 202 is deposited over the oxide layer 116, as shown in FIGS. 2D and 3A in accordance with some embodiments. In some embodiments, the dielectric layer 202 extends along the tops and the sidewalls of the fin structures 106A and 106B, as shown in FIG. 2D.

In some embodiments, the dielectric layer 202 is made of or includes a high dielectric constant (high-K) material. In some embodiments, the dielectric layer 202 has a higher dielectric constant greater than silicon nitride. The dielectric constant of the dielectric layer 202 may be greater than about 7.

In some embodiments, the dielectric layer 202 is a metal-containing oxide layer. The dielectric layer 202 may be made of or include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, one or more other suitable high-K materials, or a combination thereof. The dielectric layer 202 may be deposited using an ALD process, a CVD process, one or more other applicable processes, or a combination thereof. In some embodiments, the formation of the dielectric layer 202 involves a thermal annealing operation.

In some embodiments, the dielectric layer 202 is a single layer. In some other embodiments, the dielectric layer 202 includes multiple sub-layers. Two or more sub-layers are made of different materials or have different compositions. For example, the dielectric layer 202 includes a hafnium oxide sub-layer and a zirconium oxide sub-layer.

As shown in FIGS. 1B, 2D, and 3A, the dummy gate stacks 120A and 120B are then formed over the dielectric layer 202, in accordance with some embodiments. As shown in FIGS. 1B, 2D, and 3A, the dummy gate stacks 120A and 120B are formed to partially cover and to extend across the fin structures 106A-106B, in accordance with some embodiments. In some embodiments, the dummy gate stacks 120A and 120B wraps around the fin structures 106A-106B. As shown in FIG. 2D, the dummy gate stack 120B extends across and is wrapped around the fin structures 106A-106B.

As shown in FIGS. 2D and 3A, each of the dummy gate stacks 120A and 120B includes a dummy gate electrode 118. The dummy gate electrodes 118 may be made of or include polysilicon or another suitable material.

In some embodiments, a dummy gate electrode layer is deposited over the dielectric layer 202. For example, the dummy gate electrode layer is a polysilicon layer. The dummy gate electrode layer may be deposited using a CVD process, an ALD process, one or more other applicable processes, or a combination thereof. Afterwards, the dummy gate electrode layer are patterned to form the dummy gate electrodes 118 of the dummy gate stacks 120A and 120B, as shown in FIGS. 2D and 3A.

In some embodiments, hard mask elements including mask layers 122 and 124 are used to assist in the patterning process for forming the dummy gate stacks 120A and 120B. With the hard mask elements as an etching mask, one or more etching processes are used to partially remove the dummy gate electrode layer. As a result, remaining portions of the dummy gate electrode layer form the dummy gate electrodes 118 of the dummy gate stacks 120A and 120B.

During the one or more etching processes, the dielectric layer 202 may protect the semiconductor layers 104a-104d thereunder. In some embodiments, due to the protection of the dielectric layer 202, the semiconductor layers 104a-104d is substantially prevented from being etched during the formation of the dummy gate stacks 120A and 120B. The semiconductor layers 104a-104d that are protected may thus have good quality, which ensures the quality and reliability of the channel structures that will be formed from the semiconductor layers 104a-104d.

As shown in FIG. 3B, spacer layers 126 and 128 are deposited over the dummy gate stacks 120A and 120B and the dielectric layer 202, in accordance with some embodiments. The spacer layers 126 and 128 extend along the tops and sidewalls of the dummy gate stacks 120A and 120B, as shown in FIG. 3B.

In some embodiments, due to the protection of the dielectric layer 202, the top surface of the fin structure 106A is not recessed during the formation of the dummy gate stacks 120A and 120B. The top of the fin structure 106A may thus be maintained at the original height level, which facilitates to subsequent formation processes. The spacer layers 126 and 128 may also be prevented from extending into the fin structure 106A to occupy the space for forming the channel structures.

In some embodiments, the spacer layers 126 and 128 are made of different materials. The spacer layer 126 may be made of a dielectric material that has a low dielectric constant. The spacer layer 126 may be made of or include silicon carbide, silicon oxycarbide, carbon-containing silicon oxynitride, silicon oxide, one or more other suitable materials, or a combination thereof. In some embodiments, the spacer layer 126 is a single layer. In some other embodiments, the spacer layer 126 includes multiple sub-layers. Some of the sub-layers may be made of different materials. Some of the sub-layers may be made of similar materials with different compositions. For example, one of the sub-layers may have a greater atomic concentration of carbon than other sub-layers.

The spacer layer 128 may be made of a dielectric material that can provide more protection to the gate stacks during subsequent processes. The spacer layer 128 may have a greater dielectric constant than that of the spacer layer 126. The spacer layer 128 may be made of silicon nitride, silicon oxynitride, carbon-containing silicon nitride, carbon-containing silicon oxynitride, one or more other suitable materials, or a combination thereof. The spacer layers 126 and 128 may be sequentially deposited using a CVD process, an ALD process, a physical vapor deposition (PVD) process, one or more other applicable processes, or a combination thereof.

As shown in FIG. 3C, the spacer layers 126 and 128 are partially removed, in accordance with some embodiments. One or more anisotropic etching processes may be used to partially remove the spacer layers 126 and 128. As a result, remaining portions of the spacer layers 126 and 128 form spacer elements 126’ and 128’, respectively. The spacer elements 126’ and 128’ extend along the sidewalls of the dummy gate stacks 120A and 120B, as shown in FIG. 3C. In some embodiments, the dielectric layer 202 and the oxide layer 116 are also partially removed, as shown in FIG. 3C. In some embodiments, the edges of the dielectric layer 202 are substantially aligned with the edges of the spacer elements 126’ and 128’.

As shown in FIG. 3C, the fin structure 106A is partially removed to form recesses 130, in accordance with some embodiments. The recesses 130 may be used to contain epitaxial structures (such as source/drain structures) that will be formed later. One or more etching processes may be used to form the recesses 130. In some embodiments, a dry etching process is used to form the recesses 130. Alternatively, a wet etching process may be used to form the recesses 130. In some embodiments, each of the recesses 130 penetrates into the fin structure 106A. In some embodiments, the recesses 130 further extend into the semiconductor fin 101A, as shown in FIG. 3C. In some embodiments, the spacer elements 126’ and 128’ and the recesses 130 are simultaneously formed using the same etching process.

In some embodiments, each of the recesses 130 has slanted sidewalls. Upper portions of the recesses 130 are larger (or wider) than lower portions of the recesses 130. In these cases, due to the profile of the recesses 130, an upper semiconductor layer (such as the semiconductor layer 104d) is shorter than a lower semiconductor layer (such as the semiconductor layer 104b).

However, embodiments of the disclosure have many variations. In some other embodiments, the recesses 130 have substantially vertical sidewalls. In these cases, due to the profile of the recesses 130, an upper semiconductor layer (such as the semiconductor layer 104d) is substantially as wide as a lower semiconductor layer (such as the semiconductor layer 104b).

As shown in FIG. 3D, the semiconductor layers 102a-102d are laterally etched, in accordance with some embodiments. As a result, edges of the semiconductor layers 102a-102d retreat from edges of the semiconductor layers 104a-104d. As shown in FIG. 3D, recesses 132 are formed due to the lateral etching of the semiconductor layers 102a-102d. The recesses 132 may be used to contain inner spacers that will be formed later. The semiconductor layers 102a-102d may be laterally etched using a wet etching process, a dry etching process, or a combination thereof. In some other embodiments, the semiconductor layers 102a-102d are partially oxidized before being laterally etched.

During the lateral etching of the semiconductor layers 102a-102d, the semiconductor layers 104a-104d may also be slightly etched. As a result, edge portions of the semiconductor layers 104a-104d are partially etched and thus shrink to become edge elements 105a-105d, as shown in FIG. 3D. As shown in FIG. 3D, each of the edge elements 105a-105d of the semiconductor layers 104a-104d is thinner than the corresponding inner portion of the semiconductor layers 104a-104d.

As shown in FIG. 3E, a spacer layer 134 is deposited over the structure shown in FIG. 3D, in accordance with some embodiments. The spacer layer 134 covers the dummy gate stacks 120A and 120B and fills the recesses 132. The spacer layer 134 may be made of or include carbon-containing silicon nitride (SiCN), carbon-containing silicon oxynitride (SiOCN), carbon-containing silicon oxide (SiOC), silicon oxide, silicon nitride, one or more other suitable materials, or a combination thereof. In some embodiments, the spacer layer 134 is a single layer. In some other embodiments, the spacer layer 134 includes multiple sub-layers. Some of the sub-layers may be made of different materials and/or contain different compositions. The spacer layer 134 may be deposited using a CVD process, an ALD process, one or more other applicable processes, or a combination thereof.

As shown in FIG. 3F, one or more etching processes are used to partially remove the spacer layer 134, in accordance with some embodiments. The portions of the spacer layer 134 outside of the recesses 132 may be removed. The remaining portions of the spacer layer 134 form inner spacers 136, as shown in FIG. 3F. The etching process may include a dry etching process, a wet etching process, or a combination thereof.

The inner spacers 136 cover the edges of the semiconductor layers 102a-102d. The inner spacers 136 may be used to prevent subsequently formed epitaxial structures (that function as, for example, source/drain structures) from being damaged during a subsequent process for removing the semiconductor layers 102a-102d. In some embodiments, the inner spacers 136 are made of a low-k material that has a lower dielectric constant than that of silicon oxide. In these cases, the inner spacers 136 may also be used to reduce parasitic capacitance between the subsequently formed source/drain structures and the gate stacks. As a result, the operation speed of the semiconductor device structure may be improved.

In some embodiments, after the etching process for forming the inner spacers 136, portions of the semiconductor fin 101A originally covered by the spacer layer 134 are exposed by the recesses 130, as shown in FIG. 3F. The edges of the semiconductor layers 104a-104d are exposed by the recesses 130, as shown in FIG. 3F.

As shown in FIG. 3G, epitaxial structures 138 are formed, in accordance with some embodiments. In some embodiments, the epitaxial structures 138 fill the recesses 130, as shown in FIG. 3G. In some other embodiments, the epitaxial structures 138 overfill the recesses 130. In some other embodiments, the epitaxial structures 138 partially fill the recesses 130.

In some embodiments, the epitaxial structures 138 connect to the semiconductor layers 104a-104d. Each of the semiconductor layers 104a-104d is sandwiched between the epitaxial structures 138. In some embodiments, the epitaxial structures 138 are p-type doped regions. The epitaxial structures 138 may include epitaxially grown silicon germanium (SiGe), epitaxially grown silicon, or another suitable epitaxially grown semiconductor material.

However, embodiments of the disclosure are not limited thereto. In some other embodiments, the epitaxial structures 138 are n-type doped regions. The epitaxial structures 138 may include epitaxially grown silicon, epitaxially grown silicon carbide (SiC), epitaxially grown germanium, or another suitable epitaxially grown semiconductor material.

In some embodiments, the epitaxial structures 138 are formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof. In some embodiments, the formation of the epitaxial structures 138 involves one or more etching processes that are used to fine-tune the shapes of the epitaxial structures 138.

In some embodiments, the epitaxial structures 138 are doped with one or more suitable p-type dopants. For example, the epitaxial structures 138 are SiGe source/drain features or Si source/drain features that are doped with boron (B), gallium (Ga), indium (In), or another suitable dopant. In some other embodiments, the epitaxial structures 138 are doped with one or more suitable n-type dopants. For example, the epitaxial structures 138 are Si source/drain features doped with phosphor (P), antimony (Sb), or another suitable dopant.

In some embodiments, the epitaxial structures 138 are doped in-situ during their epitaxial growth. The initial reaction gas mixture for forming the epitaxial structures 138 contains dopants. In some other embodiments, the epitaxial structures 138 are not doped during the growth of the epitaxial structures 138 and the embedded epitaxial structures 410. Instead, after the formation of the epitaxial structures, the epitaxial structures 138 are doped in a subsequent process. In some embodiments, the doping is achieved by using an ion implantation process, a plasma immersion ion implantation process, a gas and/or solid source diffusion process, one or more other applicable processes, or a combination thereof. In some embodiments, the epitaxial structures 138 are further exposed to one or more annealing processes to activate the dopants. For example, a rapid thermal annealing process is used.

As shown in FIG. 3H, a contact etch stop layer 139 and an insulating layer 140 are formed, in accordance with some embodiments. The contact etch stop layer 139 and the insulating layer 140 cover the epitaxial structures 138 and surround the dummy gate stacks 120A and 120B. The contact etch stop layer 139 may be made of or include silicon nitride, silicon oxynitride, silicon carbide, aluminum oxide, one or more other suitable materials, or a combination thereof. The insulating layer 140 may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, one or more other suitable materials, or a combination thereof.

In some embodiments, an etch stop material layer and an insulating material layer are sequentially deposited over the structure shown in FIG. 3G. The etch stop material layer may be deposited using a CVD process, an ALD process, a PVD process, one or more other applicable processes, or a combination thereof. The insulating material layer may be deposited using an FCVD process, a CVD process, an ALD process, one or more other applicable processes, or a combination thereof.

Afterwards, a planarization process is used to partially remove the etch stop material layer and the insulating material layer. As a result, the remaining portions of the etch stop material layer and the insulating material layer respectively form the contact etch stop layer 139 and the insulating layer 140, as shown in FIG. 3H. The planarization process may include a CMP process, a grinding process, an etching process, a dry polishing process, one or more other applicable processes, or a combination thereof. In some embodiments, the mask layers 122 and 124 are removed during the planarization process. In some embodiments, after the planarization process, the top surfaces of the contact etch stop layer 139, the insulating layer 140, and the dummy gate electrodes 118 are substantially level.

As shown in FIG. 3I, the dummy gate electrodes 118 are removed to form trenches 142 using one or more etching processes, in accordance with some embodiments. The trenches 142 are surrounded by the insulating layer 140. In some embodiments, the portions of the dielectric layer 202 and the oxide layer 116 that are directly under the dummy gate electrodes 118 are also removed.

As shown in FIG. 3J, the semiconductor layers 102a-102d (that function as sacrificial layers) are removed, in accordance with some embodiments. In some embodiments, one or more etching processes are used to remove the he semiconductor layers 102a-102d. As a result, recesses 144 are formed, as shown in FIG. 3J.

Due to high etching selectivity, the semiconductor layers 104a-104d are slightly (or substantially not) etched. The remaining portions of the semiconductor layers 104a-104d form multiple semiconductor nanostructures 104a’-104d’. The semiconductor nanostructures 104a’-104d’ are constructed by or made up of the remaining portions of the semiconductor layers 104a-104d. The semiconductor nanostructures 104a’-104d’ suspended over the semiconductor fin 101A may function as channel structures of transistors.

In some embodiments, the etchant used for removing the semiconductor layers 102a-102d also slightly removes the semiconductor layers 104a-104d that form the semiconductor nanostructures 104a’-104d’. As a result, the obtained semiconductor nanostructures 104a’-104d’ become thinner after the removal of the semiconductor layers 102a-102d. In some embodiments, each of the semiconductor nanostructures 104a’-104d’ is thinner than the edge elements 105a-105d since the edge elements 105a-105d are surrounded by other elements and thus are prevented from being reached and etched by the etchant.

The recesses 144 connect to the trench 142 and surround each of the semiconductor nanostructures 104a’-104d’. As shown in FIG. 3J, even if the recesses 144 between the semiconductor nanostructures 104a’-104d’ are formed, the semiconductor nanostructures 104a’-104d’ remain being held by the epitaxial structures 138. Therefore, after the removal of the semiconductor layers 102a-102d (that function as sacrificial layers), the released semiconductor nanostructures 104a’-104d’ are prevented from falling down.

During the removal of the semiconductor layers 102a-102d (that function as sacrificial layers), the inner spacers 136 protect the epitaxial structures 138 from being etched or damaged. The quality and reliability of the semiconductor device structure are improved.

As shown in FIG. 3K, metal gate stacks 156A and 156B are formed to fill the trenches 142, in accordance with some embodiments. The metal gate stacks 156A and 156B further extend into the recesses 144 to wrap around each of the semiconductor nanostructures 104a’-104d’.

Each of the metal gate stacks 156A and 156B includes multiple metal gate stack layers. Each of the metal gate stacks 156A and 156B may include a gate dielectric layer 150 and a metal gate electrode 152. The metal gate electrode 152 may include a work function layer. The metal gate electrode 152 may further include a conductive filling. In some embodiments, the formation of the metal gate stacks 156A and 156B involves the deposition of multiple metal gate stack layers over the insulating layer 140 to fill the trenches 142 and the recesses 144. The metal gate stack layers extend into the recesses 144 to wrap around each of the semiconductor nanostructures 104a’-104d’.

In some embodiments, the gate dielectric layer 150 is made of or includes a dielectric material with high dielectric constant (high-K). The gate dielectric layer 150 may be made of or include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, one or more other suitable high-K materials, or a combination thereof. In some embodiments, the gate dielectric layer 150 is in direct contact with the dielectric layer 202. In some embodiments, the gate dielectric layer 150 is in direct contact with the spacer element 126’. The gate dielectric layer 150 may be deposited using an ALD process, a CVD process, one or more other applicable processes, or a combination thereof. The formation of the gate dielectric layer 150 may further involve a thermal operation.

In some embodiments, before the formation of the gate dielectric layer 150, an interfacial layers are formed on the surfaces of the semiconductor nanostructures 104a’-104d’. The interfacial layers are very thin and are made of, for example, silicon oxide or germanium oxide. In some embodiments, the interfacial layers are formed by applying an oxidizing agent on the surfaces of the semiconductor nanostructures 104a’-104d’. For example, a hydrogen peroxide-containing liquid may be applied or provided on the surfaces of the semiconductor nanostructures 104a’-104d’ so as to form the interfacial layers.

The work function layer of the metal gate electrode 152 may be used to provide the desired work function for transistors to enhance device performance including improved threshold voltage. In some embodiments, the work function layer is used for forming a PMOS device. The work function layer is a p-type work function layer. The p-type work function layer is capable of providing a work function value suitable for the device, such as greater than or equal to about 4.8 eV.

The p-type work function layer may include metal, metal carbide, metal nitride, other suitable materials, or a combination thereof. For example, the p-type metal includes tantalum nitride, tungsten nitride, titanium, titanium nitride, one or more other suitable materials, or a combination thereof.

In some other embodiments, the work function layer is used for forming an NMOS device. The work function layer is an n-type work function layer. The n-type work function layer is capable of providing a work function value suitable for the device, such as less than or equal to about 4.5 eV.

The n-type work function layer may include metal, metal carbide, metal nitride, or a combination thereof. For example, the n-type work function layer includes titanium nitride, tantalum, tantalum nitride, one or more other suitable materials, or a combination thereof. In some embodiments, the n-type work function is an aluminum-containing layer. The aluminum-containing layer may be made of or include TiAlC, TiAlO, TiAlN, one or more other suitable materials, or a combination thereof.

The work function layer may also be made of or include hafnium, zirconium, titanium, tantalum, aluminum, metal carbides (e.g., hafnium carbide, zirconium carbide, titanium carbide, aluminum carbide), aluminides, ruthenium, palladium, platinum, cobalt, nickel, conductive metal oxides, or a combinations thereof. The thickness and/or the compositions of the work function layer may be fine-tuned to adjust the work function level.

The work function layer may be deposited over the gate dielectric layer 150 using an ALD process, a CVD process, a PVD process, an electroplating process, an electroless plating process, one or more other applicable processes, or a combination thereof.

In some embodiments, a barrier layer is formed before the work function layer to interface the gate dielectric layer 150 with the subsequently formed work function layer. The barrier layer may also be used to prevent diffusion between the gate dielectric layer 150 and the subsequently formed work function layer. The barrier layer may be made of or include a metal-containing material. The metal-containing material may include titanium nitride, tantalum nitride, one or more other suitable materials, or a combination thereof. The barrier layer may be deposited using an ALD process, a CVD process, a PVD process, an electroplating process, an electroless plating process, one or more other applicable processes, or a combination thereof.

In some embodiments, the conductive fillings of the metal gate electrodes 152 are made of or include a metal material. The metal material may include tungsten, aluminum, copper, cobalt, one or more other suitable materials, or a combination thereof. A conductive layer used for forming the conductive filling may be deposited over the work function layer using a CVD process, an ALD process, a PVD process, an electroplating process, an electroless plating process, a spin coating process, one or more other applicable processes, or a combination thereof.

In some embodiments, a blocking layer is formed over the work function layer before the formation of the conductive layer used for forming the conductive filling. The blocking layer may be used to prevent the subsequently formed conductive layer from diffusing or penetrating into the work function layer. The blocking layer may be made of or include tantalum nitride, titanium nitride, one or more other suitable materials, or a combination thereof. The blocking layer may be deposited using an ALD process, a PVD process, an electroplating process, an electroless plating process, one or more other applicable processes, or a combination thereof.

Afterwards, a planarization process is performed to remove the portions of the metal gate stack layers outside of the trenches 142, in accordance with some embodiments. As a result, the remaining portions of the metal gate stack layers form the metal gate stacks 156A and 156B, as shown in FIG. 3K.

In some embodiments, the gate dielectric layer 150 extends along the surfaces of the semiconductor nanostructures 104a’-104d’ and the interior sidewalls of the spacer elements 126’, as shown in FIG. 3K. In some embodiments, the gate dielectric layer 150 extends upwards along the sidewall of the dielectric layer 202. In some embodiments, the top of the dielectric layer 202 is closer to the channel structure 104d’ than the top of the gate dielectric layer 150.

In some embodiments, the dielectric layer 202 that has a high dielectric constant is inserted below the spacer elements 126’ and 128’. The dielectric layer 202 may help to enhance the control of the gate stack to the channel structures. The dielectric layer 202 may help to increase the electrostatic extension of the metal gate stacks 156A and 156B. The energy barrier between the channel structure and the source/drain regions may thus be lowered. The drain induced barrier lowering (DIBL) may also be mitigated.

In some embodiments illustrated in FIGS. 3A-3K, the oxide layer is formed before the formation of the dielectric layer 202. However, embodiments of the disclosure are not limited thereto. Many variations and/or modifications can be made to embodiments of the disclosure. In some other embodiments, the oxide layer is formed after the formation of the dielectric layer 202.

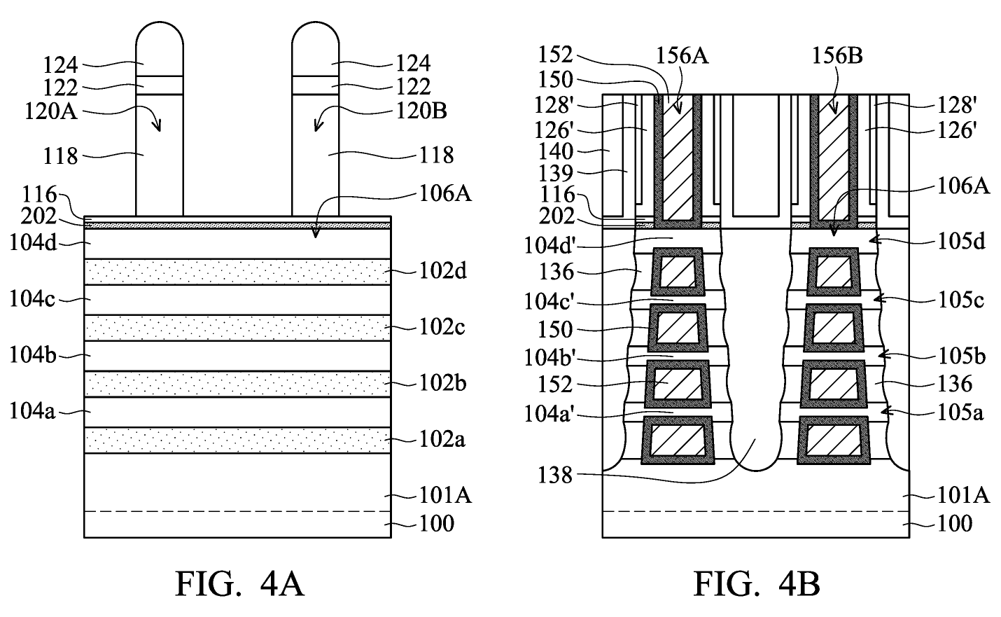

FIGS. 4A-4B are cross-sectional views of various stages of a process for forming a portion of a semiconductor device structure, in accordance with some embodiments. As shown in FIG. 4A, a structure that is similar to the structure shown in FIG. 3A is formed. Unlike the embodiments shown in FIG. 3A, the oxide layer 116 is formed after the formation of the dielectric layer 202, as shown in FIG. 4A in accordance with some embodiments.

Afterwards, the processes that are similar to those illustrated in FIGS. 3B-3K are performed. As a result, the structure shown in FIG. 4B is formed. In some embodiments, the dielectric layer 202 is in direct contact with the edge element 105d of the semiconductor nanostructure 104d’. The dielectric layer 202 that has a high dielectric constant may help to improve the reliability and performance of the semiconductor device structure.

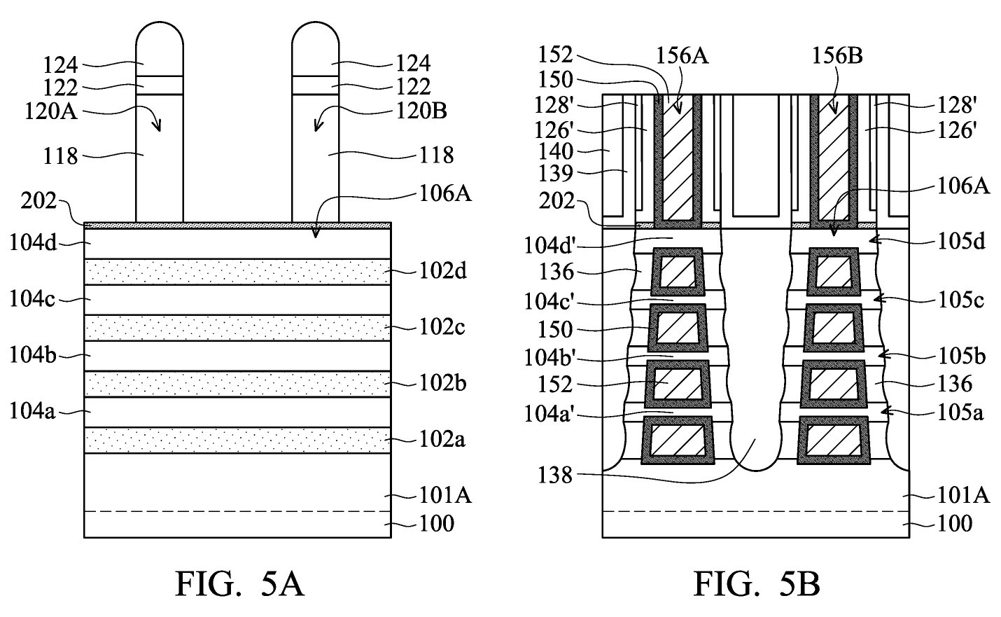

Many variations and/or modifications can be made to embodiments of the disclosure. FIGS. 5A-5B are cross-sectional views of various stages of a process for forming a portion of a semiconductor device structure, in accordance with some embodiments.

As shown in FIG. 5A, a structure that is similar to the structure shown in FIG. 3A is formed. Unlike the embodiments shown in FIG. 3A, the oxide layer 116 is not formed, as shown in FIG. 5A in accordance with some embodiments. In some embodiments, the dielectric layer 202 is in direct contact with the semiconductor layer 104d that will be formed into one or more channel structures.

Afterwards, the processes that are similar to those illustrated in FIGS. 3B-3K are performed. As a result, the structure shown in FIG. 5B is formed. In some embodiments, the dielectric layer 202 is in direct contact with the semiconductor nanostructure 104d’, the spacer element 126’, and the gate dielectric layer 150. The dielectric layer 202 that has a high dielectric constant may help to improve the reliability and performance of the semiconductor device structure.

In some embodiments, the dielectric layer 202 is inserted under the spacer elements of GAA transistors. However, embodiments of the disclosure are not limited thereto. Many variations and/or modifications can be made to embodiments of the disclosure. In some other embodiments, the dielectric layer 202 is inserted under the spacer elements of FinFET transistors. In some embodiments, the fin structures 106A and 106B does not include multiple semiconductor layers that function as sacrificial layers. In some embodiments, each of the fin structures 106A and 106B is a semiconductor fin without sacrificial layers.

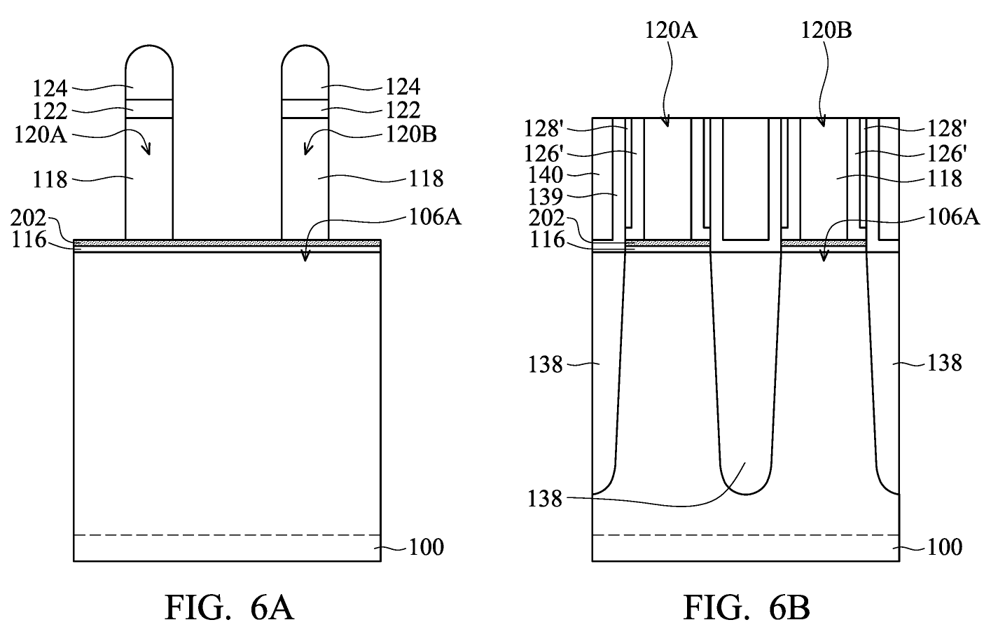

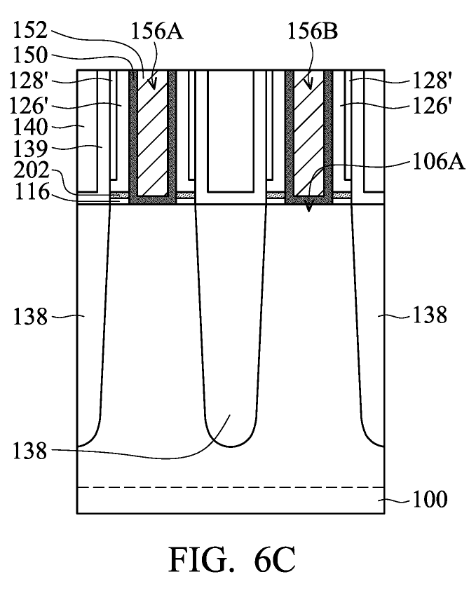

FIGS. 6A-6C are cross-sectional views of various stages of a process for forming a portion of a semiconductor device structure, in accordance with some embodiments. As shown in FIG. 6A, a structure that is similar to the structure shown in FIG. 3A is formed. Unlike the embodiments shown in FIG. 3A, the fin structure 106A is a semiconductor fin without sacrificial layers, as shown in FIG. 6A in accordance with some embodiments. The fin structure 106A may be a silicon fin, a silicon germanium fin, or a germanium fin. In some embodiments, due to the protection of the dielectric layer 202, the fin structure 106A is prevented from being recessed or damaged during the etching process for forming the dummy gate stacks 120A and 120B.

Afterwards, the processes that are similar to those illustrated in FIGS. 3B-3H are performed to form the epitaxial structures 138, the contact etch stop layer 139, and the insulating layer 140. As a result, the structure shown in FIG. 6B is formed. In some embodiments, the remaining portions of the fin structure 106A between the epitaxial structures 138 form multiple channel structures (or channel regions). Due to the protection of the dielectric layer 202, there is substantially no fin top loss on the fin structure 106A. In some embodiments, the tops of the channel structures are substantially level with the tops of the epitaxial structures 138. The quality and reliability of the channel structures are ensured.

Afterwards, the processes that are similar to those illustrated in FIGS. 3I-3K are performed to replace the dummy gate stacks 120A and 120B with the metal gate stacks 156A and 156B. As a result, the structure shown in FIG. 6C is formed.

In some embodiments, the spacer elements 126’ are separated from the spacer elements 126’ by the dielectric layer 202. In some embodiments, the dielectric layer 202 is in direct contact with the spacer elements 126’ and the gate dielectric layer 150. In some embodiments, the gate dielectric layer 150 passes through the bottom surface and the top surface of the dielectric layer 202. The dielectric layer 202 that has a high dielectric constant may help to enhance the control of the metal gate stacks 156A and 156B to the channel structures, so as to improve the reliability and performance of the semiconductor device structure.

Embodiments of the disclosure form a semiconductor device structure with a gate stack. A dielectric layer that has a high dielectric constant is inserted below the spacer element, so as to enhance the control of the gate stack to the channel structure. The dielectric layer may further help to mitigate the fin top loss during the formation process and to mitigate the drain induced barrier lowering. The performance and reliability of the semiconductor device structure are thus greatly improved.

In accordance with some embodiments, a method for forming a semiconductor device structure is provided. The method includes forming a channel structure over a substrate and forming a dielectric layer over the channel structure. The dielectric layer has a higher dielectric constant than silicon nitride. The method also includes forming a gate stack over the dielectric layer and forming a spacer element over a sidewall of the gate stack. The spacer element covers a portion of the dielectric layer.

In accordance with some embodiments, a method for forming a semiconductor device structure is provided. The method includes forming a semiconductor structure over a substrate and forming a metal-containing oxide layer over the semiconductor structure. The method also includes forming a gate stack over the metal-containing oxide layer and forming a spacer element over a sidewall of the gate stack. The spacer element covers a top of the metal-containing oxide layer.

In accordance with some embodiments, a semiconductor device structure is provided. The semiconductor device structure includes a channel structure over a substrate and a gate stack partially covering the channel structure. The semiconductor device structure also includes a spacer element extending along a sidewall of the gate stack. The semiconductor device structure further includes a metal-containing oxide layer between the spacer element and the channel structure.

The foregoing outlines features of several embodiments so that those skilled in the art may better understand the aspects of the present disclosure. Those skilled in the

art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device structure, comprising:
a channel structure over a substrate;
a gate stack partially covering the channel structure;
a gate spacer extending along a sidewall of the gate stack; and
a metal-containing oxide layer between the gate spacer and the channel structure.

2. The semiconductor device structure as claimed in claim 1, wherein the gate stack comprises a gate dielectric layer and a work function layer, the gate dielectric layer extends along a surface of the channel structure and an interior sidewall of the gate spacer.

3. The semiconductor device structure as claimed in claim 2, wherein a top of the metal-containing oxide layer is closer to the channel structure than a top of the gate dielectric layer.

4. The semiconductor device structure as claimed in claim 2, wherein the metal-containing oxide layer is in direct contact with the gate dielectric layer.

5. The semiconductor device structure as claimed in claim 2, wherein the metal-containing oxide layer is in direct contact with the interior sidewall of the gate spacer.

6. The semiconductor device structure as claimed in claim 2, wherein in a cross-sectional view, a bottommost surface of the metal-containing oxide layer is vertically located between a topmost surface of the gate dielectric layer and a top of the channel structure.

7. The semiconductor device structure as claimed in claim 1, wherein edges of the metal-containing oxide layer and the gate spacer are substantially aligned with each other.

8. The semiconductor device structure as claimed in claim 1, further comprising:
a semiconductor oxide layer between the metal-containing oxide layer and the channel structure.

9. The semiconductor device structure as claimed in claim 1, further comprising:
a semiconductor oxide layer, wherein the metal-containing oxide layer is between the semiconductor oxide layer and the channel structure.

10. The semiconductor device structure as claimed in claim 1, wherein the metal-containing oxide layer is substantially as wide as the gate spacer.

11. A semiconductor device structure, comprising:
a plurality of semiconductor nanostructures;
a gate stack wrapped around the semiconductor nanostructures, wherein the gate stack has a gate dielectric layer and a gate electrode;
a gate spacer extending along a sidewall of the gate stack; and
a dielectric layer between the gate spacer and the semiconductor nanostructures, wherein the dielectric layer has a higher dielectric constant than that of silicon nitride, and the dielectric layer is spaced apart from the semiconductor nanostructures.

12. The semiconductor device structure as claimed in claim 11, wherein in a cross-sectional view, a bottommost surface of the dielectric layer is vertically located between a topmost surface of the gate dielectric layer and an interface between the gate dielectric layer and the semiconductor nanostructures.

13. The semiconductor device structure as claimed in claim 11, further comprising:
a semiconductor oxide layer between the dielectric layer and the semiconductor nanostructures.

14. The semiconductor device structure as claimed in claim 11, further comprising:
a second dielectric layer laterally surrounding the gate stack and the gate spacer, wherein the second dielectric layer has a lower dielectric constant than that of the dielectric layer; and
an etch stop layer between the second dielectric layer and the gate spacer, wherein in a cross-sectional view, the etch stop layer vertically extends across opposite surfaces of the dielectric layer.

15. The semiconductor device structure as claimed in claim 14, wherein the etch stop layer is in direct contact with the dielectric layer and the gate spacer.

16. A semiconductor device structure, comprising:
a channel structure over a substrate;
a gate stack covering an intermediate portion of the channel structure;
a gate spacer extending along a sidewall of the gate stack and covering an edge portion of the channel structure; and
a metal-containing oxide layer between the gate spacer and the edge portion of the channel structure.

17. The semiconductor device structure as claimed in claim 16, wherein the metal-containing oxide layer is spaced apart from the channel structure.

18. The semiconductor device structure as claimed in claim 16, wherein in a cross-sectional view, a gate dielectric layer of the gate stack vertically extends across opposite surfaces of the metal-containing oxide layer.

19. The semiconductor device structure as claimed in claim 18, wherein in the cross-sectional view, an entirety of the metal-containing oxide layer is between a bottom of the gate spacer and a top of the channel structure.

20. The semiconductor device structure as claimed in claim 16, further comprising:
a semiconductor oxide layer between the channel structure and the metal-containing oxide layer, wherein the metal-containing oxide layer has a higher dielectric constant than that of the semiconductor oxide layer.
